(19) United States
(12) Patent Application Publication
(10) Pub. No.: US 2025/0098136 A1
(43) Pub. Date: Mar. 20, 2025

(54) PROCESS CONTROL DEVICE

(71) Applicant: FUJI CORPORATION, Chiryu (JP)

(72) Inventor: Teruyuki OHASHI, Anjo-shi (JP)

(73) Assignee: FUJI CORPORATION, Chiryu (JP)

(21) Appl. No.: 18/718,071

(22) PCT Filed: Jan. 19, 2022
(86) PCT No.: PCT/JP2022/001851

§ 371 Date: Jun. 10, 2024

(51) Int. Cl. H05K 13/08; H05K 13/02; H05K 13/04

(52) U.S. Cl. CPC H05K 13/085; H05K 13/02; H05K 13/0409; H05K 13/0812

(57) ABSTRACT

A process control device includes: a determination section configured to determine, before causing a mounting device to execute a mounting process of mounting a component on a board, whether to cause the mounting device to confirm, for multiple processes included in the mounting process, an operation for achieving each process; and a confirmation control section configured to, when determined that the mounting device needs to be caused to confirm a first operation for achieving a first process among the multiple processes and the mounting device does not need to be caused to confirm a second operation for achieving a second process among the multiple processes, cause the mounting device to confirm the first operation without causing the mounting device to confirm the second operation.

### TECHNICAL FIELD

The technology disclosed herein relates to a process control device that controls a mounting process of mounting a component on a board.

### BACKGROUND ART

Patent Literature 1 discloses a technique of, before a component with no mounting achievement is mounted on a board to produce a circuit board, actually mounting the component on a board and confirming the success or failure of the mounting.

### PATENT LITERATURE

Patent Literature 1: JP-A-2014-241328

### SUMMARY OF THE INVENTION

### Technical Problem

A process of actually mounting a component with no mounting achievement on a board includes various processes. The various processes include, for example, a process of causing the head to pick up a component supplied from a feeder, and a process of causing the head to mount the picked up component on the board. In Patent Literature 1, no consideration is given to the various processes described above. In the technique of Patent Literature 1, all of the various processes described above can be executed in confirming the success or failure of the mounting.

The present description provides a technique for confirming an operation of a mounting device in consideration of circumstances of multiple processes included in a mounting process.

### Solution to Problem

A process control device disclosed herein includes: a determination section configured to determine, before causing a mounting device to execute a mounting process of mounting a component on a board, whether to cause the mounting device to confirm, for multiple processes included in the mounting process, an operation for achieving each process: and a confirmation control section configured to, when determined that the mounting device needs to be caused to confirm a first operation for achieving a first process among the multiple processes and the mounting device does not need to be caused to confirm a second operation for achieving a second process among the multiple processes, cause the mounting device to confirm the first operation without causing the mounting device to confirm the second operation.

With the configuration, while the first operation for achieving the first step among the multiple processes is confirmed, the second operation for achieving the second process among the multiple processes is not confirmed. That is, all of the multiple operations for achieving the multiple processes are not executed, and only some of the multiple operations are executed. For example, it is possible to prevent the second operation that has been confirmed in the past from being confirmed again. The operation of the mounting device to be confirmed can be confirmed in consideration of multiple processes included in the mounting process.

### BRIEF DESCRIPTION OF DRAWINGS

FIG. 1 illustrates a component mounting system according to an example.

FIG. 2 illustrates a data structure of part data.

FIG. 3 is a conceptual view of a mounting device.

FIG. 4 illustrates a flowchart of processing of a server.

FIG. 5 illustrates a flowchart of production preparation processing.

FIG. 6 illustrates a flowchart of operation determination processing.

FIG. 7 illustrates a flowchart of processing of the mounting device.

### DESCRIPTION OF EMBODIMENTS

Main features of examples described below are listed. Technical elements described below are independent technical elements, respectively, exhibit technical usefulness independently or in various combinations, and are not limited to the combinations disclosed in the claims as originally filed.

(Feature 1) The process control device may further include a memory configured to store multiple setting values for executing the mounting process, in which the determination section is configured to, when one or more setting values for executing the first process among the multiple setting values are changed after the first process was executed in the past, determine that the mounting device needs to be caused to confirm the first operation for achieving the first process, and when none of the setting values for executing the second process is changed among the multiple setting values after the second process was executed in the past, determine that the mounting device does not need to be caused to confirm the second operation for achieving the second process.

When one or more set values for executing the specific process are changed after the specific process was executed in the past, there is a high possibility that the operation for achieving the specific process is changed from the operation confirmed in the past. On the other hand, when none of the setting values for executing the specific process is changed after the specific process was executed in the past, there is a high possibility that the operation for achieving the specific process is not changed from the operation confirmed in the past. With the configuration, it is possible to determine whether there is a confirmation of the first operation and the second operation by using whether there is a change in the setting value.

(Feature 2) The mounting device may include: a feeder configured to supply the component into the mounting device: a nozzle configured to pick up the component supplied by the feeder: a mounting unit configured to mount the component picked up by the nozzle on the board: and a camera configured to capture an image of the component picked up by the nozzle, and the multiple processes may include a process of causing the nozzle to pick up the component supplied by the feeder, a process of analyzing the image captured by the camera, and a process of causing the mounting unit to mount the component picked up by the nozzle on the board.

With such a configuration, it is possible to determine, for each of the pickup process, the analysis process, and the mounting process, whether there is a confirmation of the operation for achieving each process.

### EXAMPLE

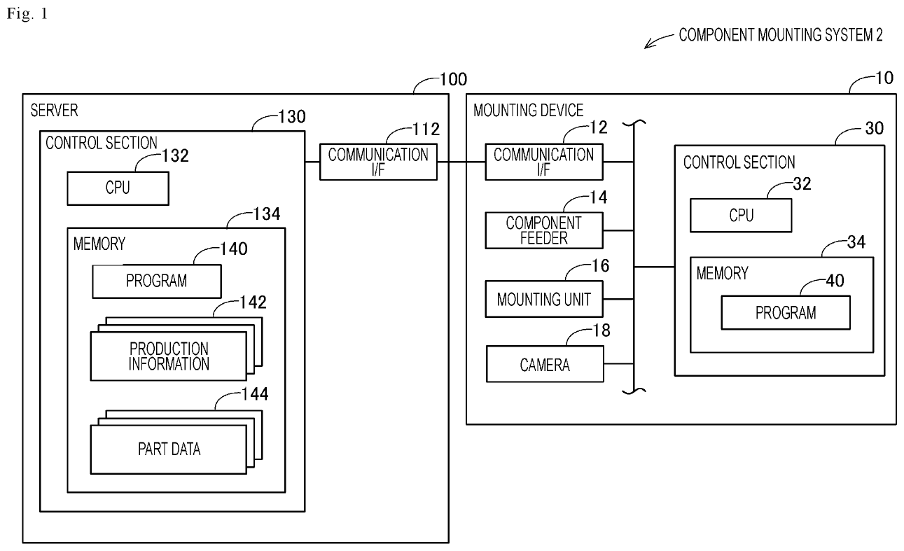

### Component Mounting System 2: FIGS. 1, 2, and 3

As illustrated in FIG. 1, component mounting system 2 includes mounting device 10 and server 100. Mounting device 10 and server 100 are communicably connected via communication means. The communication means is, for example, a local area network. The local area network may be wired or wireless. In a modification example, the communication means may include the internet, and in this case, server 100 may be a server on the Internet.

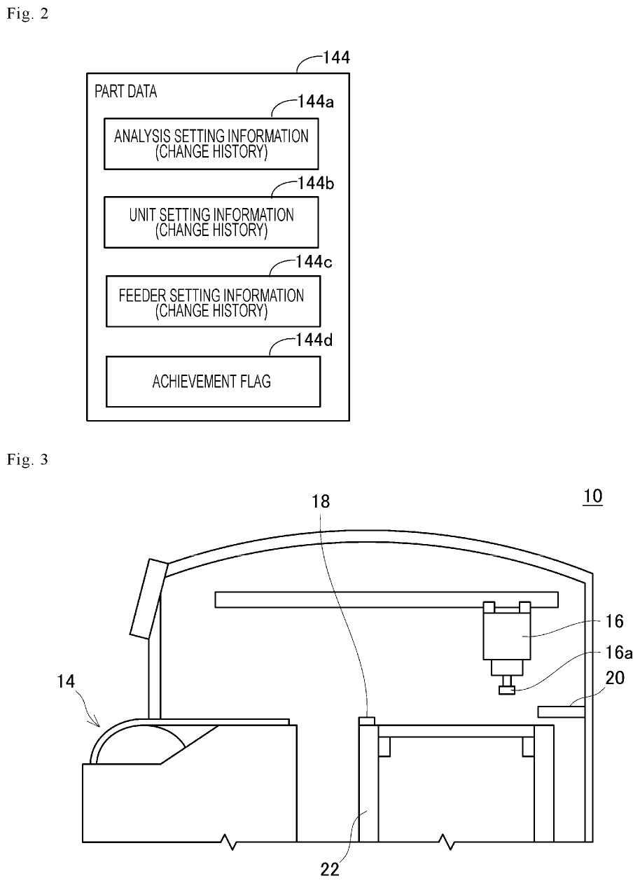

### Configuration of Mounting Device 10: FIGS. 1 and 3

Mounting device 10 is a device capable of executing a mounting process of mounting an electronic component on a board and producing a large number of circuit boards. Mounting device 10 includes communication interface 12, component feeder 14, mounting unit 16, camera 18, and control section 30. Hereinafter, the “interface” is referred to as an “I/F”. Communication I/F 12 is an I/F for executing communication with server 100.

FIG. 3 is a schematic view of a cross section of mounting device 10 as viewed from a board conveyed-in direction. Mounting device 10 includes nozzle box 20 and support table 22 in addition to sections 12, 14, 16, 18, and 30. In FIG. 3, the illustration of communication I/F 12 and control section 30 is omitted.

Component feeder 14 is a detachable cartridge that accommodates multiple electronic components. FIG. 3 illustrates a tape-type feeder that serves as component feeder 14 and accommodates multiple electronic components on a wound tape. Mounting device 10 can also attach other types of feeders, such as a tray-type feeder or a bulk-type feeder, as component feeder 14. The tray-type feeder accommodates multiple electronic components on a tray. The bulk-type feeder randomly accommodates multiple electronic components in a container.

Support table 22 is a table for supporting the board conveyed into mounting device 10. Mounting unit 16 mounts the electronic component supplied from component feeder 14 on the board on support table 22. Mounting unit 16 is movable in a horizontal plane (a left-right direction of the paper surface and a direction orthogonal to the paper surface). Nozzle 16a for picking up an electronic component in component feeder 14 is attached to the tip of mounting unit 16. The height of nozzle 16a (the position in an up-down direction of the paper surface) can be adjusted. There are various types of nozzles 16a. A specific type of nozzle 16a is selected from various nozzles 16a according to the type of electronic component to be picked up.

Camera 18 is a camera that captures an image of nozzle 16a picking up the electronic component from below. In FIG. 3, camera 18 is disposed on support table 22. Nozzle box 20 is a box that accommodates multiple nozzles 16a used in production of the circuit board. Nozzle box 20 is a detachable cartridge. The arrangement of camera 18 and nozzle box 20 in FIG. 3 is merely an example.

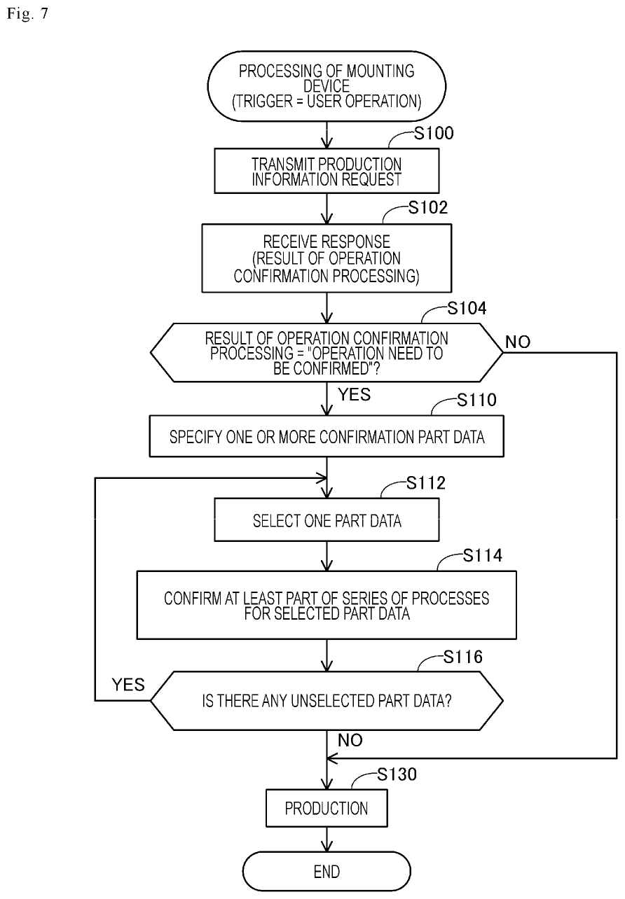

Control section 30 includes CPU 32 and memory 34. CPU 32 executes various types of processing in accordance with program 40 stored in memory 34. Memory 34 includes a volatile memory, a nonvolatile memory, or the like. Program 40 is a program for controlling sections 12, 14, 16, and 18. Program 40 achieves a mounting process and an operation confirmation (refer to FIG. 7) described later.

### Configuration of Server 100: FIGS. 1 and 2

Server 100 is a device that manages information for mounting device 10 to execute a mounting process. In a modification example, a terminal device such as a desktop PC, a laptop PC, or a tablet terminal may achieve the function of server 100.

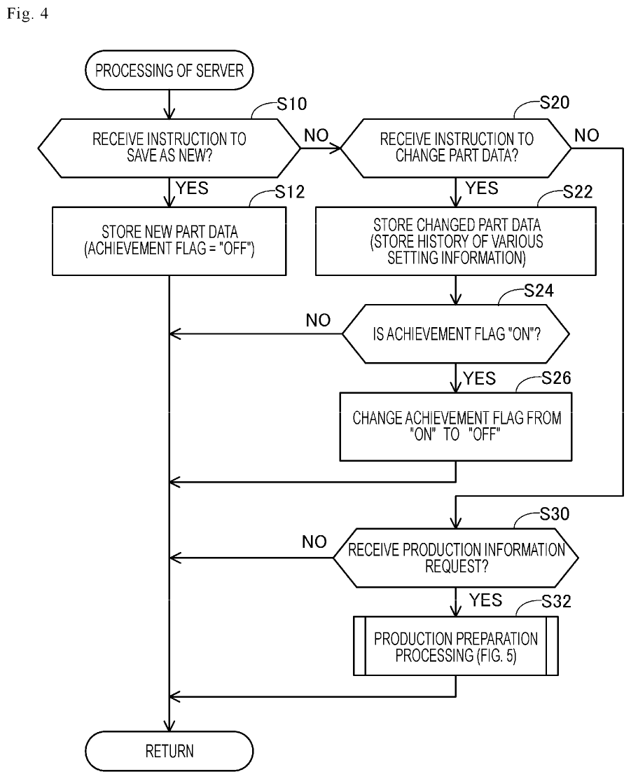

Server 100 includes communication I/F 112 and control section 130. Communication I/F 112 is an I/F for executing communication with mounting device 10. Control section 130 includes CPU 132 and memory 134. CPU 132 executes various types of processing in accordance with program 140 stored in memory 134. Program 140 is a program for managing various information related to mounting device 10. The processing shown in FIGS. 4 to 6, which will be described later, is achieved by program 140.

Memory 134 further stores multiple pieces of production information 142 corresponding to multiple types of mounting processes and multiple pieces of part data 144 corresponding to multiple types of electronic components. Production information 142 is information indicating the corresponding mounting process. Production information 142 includes, for the corresponding mounting process, component information indicating one or more types of electronic components to be mounted in the mounting process, the order information indicating the mounting order of the one or more types of electronic components to be mounted in the mounting process, the layout information indicating a layout on a board of the one or more types of electronic components to be mounted in the mounting process, and other information. The component information includes, for example, a component name of the electronic component.

Part data 144 is information related to the corresponding electronic component. Part data 144 includes analysis setting information 144a, unit setting information 144b, feeder setting information 144c, and achievement flag 144d. Analysis setting information 144a is information for analyzing the image captured by camera 18. For example, analysis setting information 144a is an image indicating the correct position and the correct orientation of the corresponding electronic component picked up by nozzle 16a. By comparing the image captured by camera 18 with the image indicated by analysis setting information 144a, it is possible to analyze whether the corresponding electronic component is correctly picked up by nozzle 16a.

Unit setting information 144b includes information indicating the type of nozzle 16a used for picking up the corresponding electronic component, and information indicating the movement speed of mounting unit 16, the height of nozzle 16a, and the like after picking up the corresponding electronic component.

Feeder setting information 144c is information indicating a type (for example, a tape-type) of component feeder 14 that supplies the corresponding electronic component.

Analysis setting information 144a, unit setting information 144b, and feeder setting information 144c can be changed by the user of server 100. Each setting information 144a, 144b, and 144c respectively can store a change history.

Achievement flag 144d indicates any value of “ON” indicating that there is an achievement (hereinafter, referred to as a “mounting achievement”) of actually performing the mounting of the corresponding electronic component on the board and “OFF” indicating that there is no mounting achievement.

Part data 144 is associated with the component information in production information 142. Server 100 acquires one or more pieces of part data 144 used in the mounting process indicated by production information 142 from multiple pieces of part data 144 in memory 134 using the component information in production information 142.

The mounting process indicated by production information 142 (that is, the process of producing a circuit board) includes, for one or more types of electronic components corresponding to one or more pieces of part data 144, a pickup process, an analysis process, and an attachment process. The pickup process is a process of causing nozzle 16a to pick up the electronic component supplied by component feeder 14 using unit setting information 144b and feeder setting information 144c. The analysis process is a process of analyzing whether the electronic component is correctly picked up by nozzle 16a using analysis setting information 144a. The attachment process is a process of controlling mounting unit 16 using unit setting information 144b to cause mounting unit 16 to mount the electronic component picked up by nozzle 16a on the board. The pickup process, the analysis process, and the attachment process are a series of processes executed in this order. When a series of processes is executed for a specific electronic component, achievement flag 144d in part data 144 corresponding to the specific electronic component is changed from “OFF” to “ON”.

In the present example, before causing mounting device 10 to execute a mounting process which is a process of producing a large number of circuit boards, mounting device 10 is caused to confirm, for at least one of the series of processes described above, an operation for achieving the process. For example, an operation for an electronic component with no mounting achievement is confirmed. The mounting process is executed on condition that the confirmation of the operation is satisfactory. It is possible to prevent a large number of defective circuit boards from being produced due to unsatisfactory operation without confirming the operation.

### Processing of Server 100: FIGS. 4 to 6

Processing executed by CPU 132 of server 100 in accordance with program 140 will be described with reference to FIGS. 4 to 6. The processing of FIG. 4 is started with the turning on of the power supply of server 100 as a trigger.

CPU 132 executes the monitoring of S10, S20, and S30. In S10, CPU 132 monitors reception of an instruction to save as new from an operating device capable of operating server 100 (not illustrated, for example, a desktop PC). The instruction to save as new is an instruction to store new part data 144 in memory 134. The instruction to save as new includes new part data 144. New part data 144 is generated using, for example, a program in the operating device. When an instruction to save as new is received from the operating device (YES in S10), CPU 132 proceeds to S12.

In S12, CPU 132 stores new part data 144 included in the instruction to save as new of S10 in memory 134. The electronic component corresponding to new part data 144 has never been actually mounted on the board. Achievement flag 144d of new part data 144 indicates “OFF” by default. When S12 ends, CPU 132 returns to the monitoring of S10, S20, and S30.

In S20, CPU 32 monitors the reception of an instruction to change part data from the operating device. The instruction to change part data is an instruction to change at least one of setting information 144a, 144b, and 144c in part data 144 stored in memory 134. The instruction to change part data includes information for specifying part data 144 to be changed (for example, a component name) and information indicating the content of change. The information indicating the content of change is generated using, for example, a program in the operating device. When the instruction to change part data is received from the operating device (YES in S20), CPU 132 proceeds to S22.

In S22, CPU 132 changes each setting information of part data 144 stored in memory 134 in accordance with the instruction to change part data, and stores changed part data 144 in memory 134. Further, CPU 132 stores each setting information before change in memory 134 as a change history.

In S24, CPU 132 determines whether achievement flag 144d in part data 144 specified by the instruction to change part data (hereinafter, referred to as “specified achievement flag 144d”) indicates “ON”. When determining that specified achievement flag 144d indicates “OFF” (NO in S24), CPU 132 skips S26 described later and returns to the monitoring of S10, S20, and S30.

When determining that specified achievement flag 144d indicates “ON” (YES in S24), CPU 132 proceeds to S26. In S26, CPU 132 changes specified achievement flag 144d from “ON” to “OFF”. When S26 ends, CPU 132 returns to the monitoring of S10, S20, and S30.

In S30, CPU 132 monitors the reception of a production information request from mounting device 10 via communication I/F 112. The production information request is a signal for requesting specific production information 142 among multiple pieces of production information 142 in memory 134. The production information request includes information for designating specific production information 142 (for example, information for identifying a mounting process).

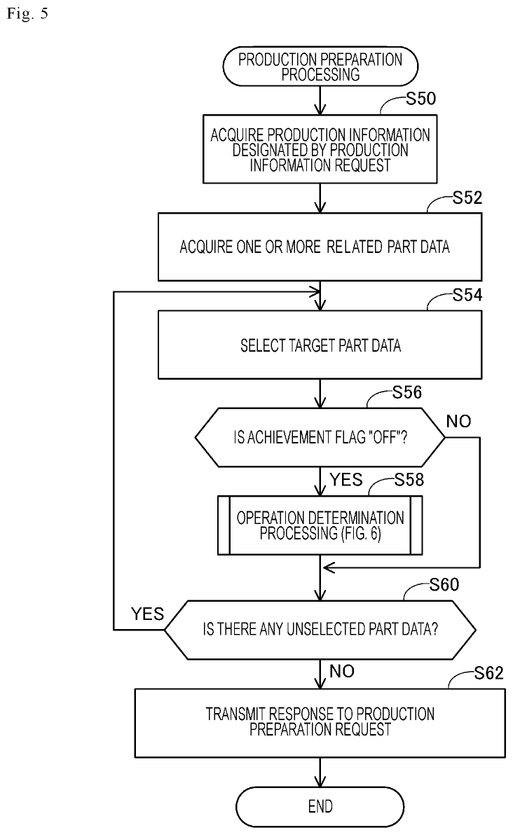

When the production information request is received from mounting device 10 (YES in S30), CPU 132 proceeds to S32. In S32, CPU 132 executes production preparation processing described later with reference to FIG. 5. When S32 ends, CPU 132 returns to the monitoring of S10, S20, and S30.

### Production Preparation Processing: FIG. 5

In S50, CPU 132 acquires specific production information 142 designated in the production information request in S30 of FIG. 4 from the multiple pieces of production information 142 in memory 134.

In S52, CPU 132 acquires one or more pieces of part data 144 associated with the component information in specific production information 142 from the multiple pieces of part data 144 in memory 134 (hereinafter, referred to as “one or more pieces of related part data 144”).

In S54, CPU 132 selects one piece of part data 144 from one or more pieces of related part data 144 (hereinafter described as “target part data 144”).

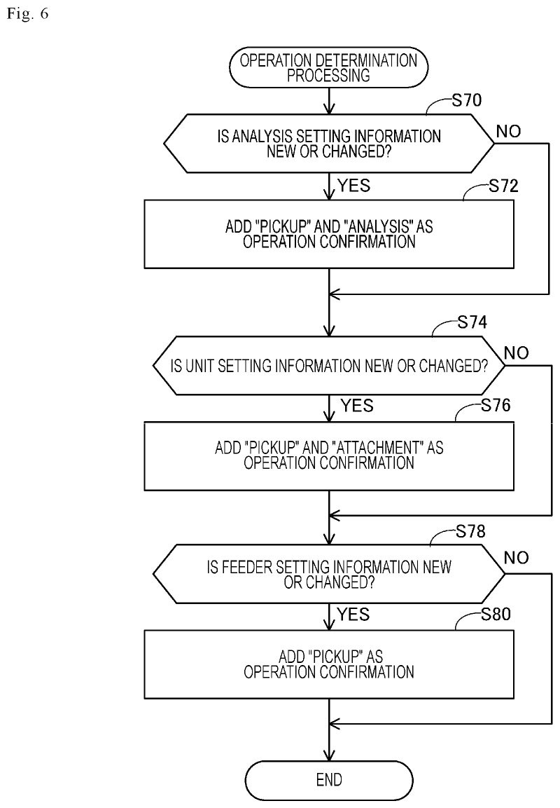

In S56, CPU 132 determines whether achievement flag 144d in target part data 144 indicates “OFF”. When determining that achievement flag 144d in target part data 144 indicates “OFF” (YES in S56), CPU 132 proceeds to S58. In S58, CPU 132 executes operation determination processing described later with reference to FIG. 6. The operation determination processing is processing for determining whether to confirm which of the series of operations for achieving a series of processes (that is, the pickup process, the analysis process, and the attachment process), for the electronic component corresponding to target part data 144. When S58 ends, CPU 132 proceeds to S60. On the other hand, when determining that achievement flag 144d in target part data 144 indicates “ON” (NO in S56), CPU 132 skips S58 and proceeds to S60.

In S60, CPU 132 determines whether there is unselected part data 144 in one or more pieces of related part data 144. When determining that there is unselected part data 144 in one or more pieces of related part data 144 (YES in S60), CPU 132 returns to S54. On the other hand, when determining that there is no unselected part data 144 in one or more pieces of related part data 144 (NO in S60), CPU 132 proceeds to S62.

In S62, CPU 132 transmits a response to the production information request in S30 of FIG. 4 to mounting device 10 via communication I/F 112. The response includes specific production information 142 designated by the production information request, one or more pieces of related part data 144, and information indicating the result of the operation determination processing in S58. When S62 ends, the processing of FIG. 5 ends.

### Operation Determination Processing: FIG. 6

In S70, CPU 132 determines whether analysis setting information 144a in target part data 144 is new, or whether analysis setting information 144a is changed after the electronic component corresponding to target part data 144 (hereinafter, referred to as a “target electronic component”) was mounted in the past. This determination is executed using the change history of analysis setting information 144a in target part data 144. When determining that analysis setting information 144a in target part data 144 is new or analysis setting information 144a is changed (YES in S70), CPU 32 proceeds to S72. On the other hand, when determining that analysis setting information 144a in target part data 144 is not new and analysis setting information 144a is not changed (NO in S70), CPU 32 skips S72 and proceeds to S74.

In S72, CPU 132 adds the pickup process and the analysis process among the series of processes as processes for which the operations need to be confirmed. When S72 ends, CPU 132 proceeds to S74.

S74 is the same as S70, except that unit setting information 144b in target part data 144 is used. When determining that unit setting information 144b in target part data 144 is new or unit setting information 144b is changed after the target electronic component was mounted in the past (YES in S74), CPU 132 proceeds to S76. On the other hand, when determining that unit setting information 144b in target part data 144 is not new and unit setting information 144b is not changed (NO in S74), CPU 32 skips S76 and proceeds to S78.

In S76, CPU 132 adds the pickup process and the attachment process among the series of processes as processes for which the operations need to be confirmed. When S76 ends, CPU 132 proceeds to S78.

S78 is the same as S70, except that feeder setting information 144c in target part data 144 is used. When determining that feeder setting information 144c in target part data 144 is new or feeder setting information 144c is changed after the target electronic component was mounted in the past (YES in S78), CPU 132 proceeds to S80. On the other hand, when determining that feeder setting information 144c in target part data 144 is not new and feeder setting information 144c is not changed (NO in S78), CPU 32 skips S80 and ends the processing of FIG. 6.

In S80, CPU 132 adds the pickup process among the series of processes as a process for which the operation needs to be confirmed. When S80 ends, CPU 132 ends the processing of FIG. 6.

### Processing of Mounting Device 10: FIG. 7

Processing executed by CPU 32 of mounting device 10 in accordance with program 40 will be described with reference to FIG. 7. The process in FIG. 7 is started when the user performs a predetermined operation on mounting device 10 as a trigger.

In S100, CPU 32 transmits a production information request to server 100 via communication I/F 12 (refer to S30 of FIG. 4). In S102, CPU 32 receives a response to the production information request in S100 from server 100 via communication I/F 12 (refer to S62 of FIG. 5). As described above, the response includes information indicating the result of the operation determination processing. For example, in the operation determination processing of FIG. 6, a case is assumed, where it is determined that each setting information 144a, 144b, and 144c is to be unchanged for all of one or more pieces of related part data 144 (NO in S70, NO in S74, and NO in S80). In this case, the result of the operation determination processing indicates that none of the operations for all of one or more pieces of related part data 144 needs to be confirmed. For example, a case is assumed, where it is determined that analysis setting information 144a is changed and remaining setting information 144b and 144c is not changed, for only first part data 144 among one or more pieces of related part data 144 (YES in S70, NO in S74, and NO in S80). In this case, the result of the operation determination processing indicates that the operations of the pickup process and the analysis process for first part data 144 need to be confirmed, and indicates that none of the operations for remaining other part data 144 among one or more pieces of related part data 144 needs to be confirmed.

In S104, when the result of the operation determination processing in the response in S102 indicates that the operation for at least one piece of part data 144 among one or more pieces of related part data 144 needs to be confirmed (YES in S104), CPU 32 proceeds to the processing in S110 onwards. On the other hand, when the result of the operation determination processing in the response in S102 indicates that none of the operations for all of one or more pieces of related part data 144 needs to be confirmed (NO in S104), CPU 32 skips the processing in S110 onwards and proceeds to S130.

In S110, CPU 32 specifies one or more pieces of part data 144 for which the need to confirm the operation is indicated in the result of the operation determination processing from one or more pieces of part data 144 included in the response in S102 (hereinafter, referred to as “one or more pieces of confirmation part data 144”).

In S112, CPU 32 selects one piece of part data 144 from one or more pieces of confirmation part data 144.

In S114, CPU 32 confirms at least a part of the series of processes for one piece of part data 144 selected in S112, based on the result of the operation determination processing in the response in S102. For example, when YES is determined in S70, NO is determined in S74, and NO is determined in S80 of FIG. 6 for one piece of part data 144 selected in S112, the pickup process and the analysis process among the series of processes are confirmed, while the attachment process is not confirmed. In addition, for example, when NO is determined in S70, YES is determined in S74, and YES is determined in S80 of FIG. 6 for one piece of part data 144 selected in S112, the pickup process and the attachment process among the series of processes are confirmed, while the analysis process is not confirmed.

When it is confirmed in S114 that the operation is satisfactory, CPU 32 proceeds to S116. On the other hand, although illustration is omitted, when it is confirmed in S114 that the operation is not satisfactory, CPU 32 ends the processing of FIG. 7 and notifies the user that the operation is not satisfactory.

In S116, CPU 32 determines whether there is unselected part data 144 in one or more pieces of confirmation part data 144. When determining that there is unselected part data 144 in one or more pieces of confirmation part data 144 (YES in S116), CPU 32 returns to S112. On the other hand, when determining that there is no unselected part data 144 in one or more pieces of confirmation part data 144 (S116: NO), CPU 32 proceeds to S130.

In S130, CPU 32 starts the mounting process indicated by specific production information 142 included in the response in S102. Thus, a large number of circuit boards are produced. In the mounting process, CPU 32 transmits an instruction to change achievement flag 144d of part data 144 from “OFF” to “ON” to server 100 for one or more pieces of related part data 144 included in the response in S102. Accordingly, achievement flag 144d in server 100 is changed from “OFF” to “ON”. When S130 ends, the processing of FIG. 7 ends.

### Effects of Present Example

With the configuration of the present example, for example, when NO is determined in S70, NO is determined in S74, and YES is determined in S78 of FIG. 6, while the operation for achieving the pickup process among the series of processes is confirmed, the operations for achieving the analysis process and the attachment process among the series of processes are not confirmed. That is, all of the operations of the three processes (that is, the pickup process, the analysis process, and the attachment process) for achieving a series of processes are not executed, and only some of the three operations are executed. For example, it is possible to prevent the operation that has been confirmed in the past from being confirmed again. The operation of the mounting device can be confirmed in consideration of a series of processes (that is, multiple processes) included in the mounting process.

As described above, analysis setting information 144a is information used in the analysis process. For example, when analysis setting information 144a in target part data 144 is changed after the mounting process of the target electronic component was executed in the past, there is a high possibility that the operation for achieving the analysis process is changed from the operation confirmed in the past. On the other hand, when analysis setting information 144a in target part data 144 is not changed after the mounting process of the target electronic component was executed in the past, there is a high possibility that the operation for achieving the analysis process is not changed from the operation confirmed in the past. According to the above example, when analysis setting information 144a in target part data 144 is changed after the mounting process of the target electronic component was executed in the past (YES in S70), server 100 adds the analysis process among the series of processes as a process for which the operation needs to be confirmed (S72). On the other hand, when analysis setting information 144a in target part data 144 is not changed after the mounting process of the target electronic component was executed in the past (NO in S70), server 100 does not add the analysis process as a process for which the operation needs to be confirmed. It is possible to determine whether there is a confirmation of the operation for achieving the analysis process by using whether there is a change in analysis setting information 144a. With respect to other pieces of setting information 144b and 144c, it is possible to determine whether there is a confirmation of the operation for achieving the process using each setting information 144b and 144c (for example, the pickup process) by using whether there is a change in each setting information 144b and 144c (S74 and S78).

### Correspondence Relationship

Mounting device 10, component feeder 14, nozzle 16a, mounting unit 16, and camera 18 are examples of a “mounting device”, a “feeder”, a “nozzle”, a “mounting unit”, and a “camera”, respectively. Control section 130 of server 100 and control section 30 of mounting device 10 are examples of a “determination section” and a “confirmation control section”, respectively. Memory 134 is an example of a “memory”. A system including control section 130 and control section 30 is an example of a “process control device”. The pickup process, the analysis process, and the attachment process are examples of “multiple processes”. In FIG. 6, when YES is determined in S70, NO is determined in S74, and NO is determined in S78, the pickup process and the analysis process are examples of the “first process”, and the attachment process is an example of the “second process”. Each setting information 144a, 144b, and 144c is an example of “multiple setting values”.

The points of attention relating to the display device and the system described in the example will be described. The “multiple processes” are not limited to the series of three processes (that is, the pickup process, the analysis process, and the attachment process), and may be two processes (for example, the pickup process and the attachment process) or four or more processes (for example, the pickup process, the first analysis process, the attachment process, and the second analysis process).

In the above example, server 100 determines whether to confirm any of a series of operations for achieving a series of processes (FIG. 6). Alternatively, mounting device 10 may perform the determination. In this case, component mounting system 2 need not include server 100, and control section 30 of mounting device 10 may have the function of control section 130 of server 100. In the present modification example, control section 30 of mounting device 10 is an example of a “determination section”.

In the above example, server 100 determines whether to confirm any of a series of operations by using whether there is a change in each setting information (FIG. 6). Alternatively, server 100 may determine whether to confirm any of a series of operations by using other conditions, such as whether there is an instruction from the user and whether a predetermined time has elapsed since each setting information is saved as new. In the present modification example, “one or more setting values” can be omitted.

The mode of achievement flag 144d is not limited to the mode of the example. For example, an individual achievement flag may be set for each of the three pieces of setting information 144a, 144b, and 144c.

The technical elements described in the present description or the drawings exhibit technical usefulness independently or in various combinations and are not limited to the combinations described in the claims as originally filed. In addition, the technique described in the present description or the drawings simultaneously achieves multiple purposes, and has technical usefulness with achieving one purpose itself of the multiple purposes.

### REFERENCE SIGNS LIST

2: component mounting system
10: mounting device
12: communication I/F
14: component feeder
16: mounting unit
16a: nozzle
18: camera
20: nozzle box
22: support table
3): control section
32: CPU
34: memory
40: program
100: server
112: communication I/F
130: control section
132: CPU
134: memory
140: program
142: production information
144: part data
144a: analysis setting information
144b: unit setting information
144c: feeder setting information
144d: achievement flag

1. A process control device comprising:
a determination section configured to determine, before causing a mounting device to execute a mounting process of mounting a component on a board, whether to cause the mounting device to confirm, for multiple processes included in the mounting process, an operation for achieving each process; and
a confirmation control section configured to, when determined that the mounting device needs to be caused to confirm a first operation for achieving a first process among the multiple processes and the mounting device does not need to be caused to confirm a second operation for achieving a second process among the multiple processes, cause the mounting device to confirm the first operation without causing the mounting device to confirm the second operation.

2. The process control device according to claim 1, further comprising:
a memory configured to store multiple setting values for executing the mounting process, wherein the determination section is configured to,
when one or more setting values for executing the first process among the multiple setting values are changed after the first process was executed in the past, determine that the mounting device needs to be caused to confirm the first operation for achieving the first process, and
when none of the setting values for executing the second process is changed among the multiple setting values after the second process was executed in the past, determine that the mounting device does not need to be caused to confirm the second operation for achieving the second process.

3. The process control device according to claim 1,
wherein the mounting device includes
a feeder configured to supply the component into the mounting device,
a nozzle configured to pick up the component supplied by the feeder,
a mounting unit configured to mount the component picked up by the nozzle on the board, and
a camera configured to capture an image of the component picked up by the nozzle, and
the multiple processes include
a process of causing the nozzle to pick up the component supplied by the feeder,
a process of analyzing an image captured by the camera, and
a process of causing the mounting unit to mount the component picked up by the nozzle on the board.
